(19) United States
(12) Patent Application Publication
(10) Pub. No.: US 2011/0126878 A1
(43) Pub. Date: Jun. 2, 2011

(54) INTERCONNECT TECHNOLOGIES FOR BACK CONTACT SOLAR CELLS AND MODULES

(76) Inventors: Peter Hacke, Albuquerque, NM (US); David H. Meakin, Albuquerque, NM (US); James M. Gee, Albuquerque, NM (US); Sysavanh Southimath, Albuquerque, NM (US); Brian Murphy, Albuquerque, NM (US)

(21) Appl. No.: 12/952,018

(22) Filed: Nov. 22, 2010

Related U.S. Application Data
(63) Continuation of application No. 11/963,841, filed on Dec. 23, 2007, now abandoned.
(60) Provisional application No. 60/871,717, filed on Dec. 22, 2006.

(51) Int. Cl. H01L 31/05

(52) U.S. Cl. 136/244

(57) ABSTRACT

Methods and systems for interconnecting back contact solar cells. The solar cells preferably have reduced area busbars, or are entirely busbarless, and current is extracted from a variety of points on the interior of the cell surface. The interconnects preferably relieve stresses due to solder reflow and other thermal effects. The interconnects may be stamped and include external or internal structures which are bonded to the solder pads on the solar cell. These structures are designed to minimize thermal stresses between the interconnect and the solar cell. The interconnect may alternatively comprise porous metals such as wire mesh, wire cloth, or expanded metal, or corrugated or fingered strips. The interconnects are preferably electrically isolated from the solar cell by an insulator which is deposited on the cell, placed on the cell as a discrete layer, or laminated directly to desired areas of the interconnect.

### CROSS-REFERENCE TO RELATED APPLICATIONS

This application is a continuation of co-pending U.S. patent application Ser. No. 11/963,841, filed Dec. 23, 2007, which claims priority to and the benefit of filing of U.S. Provisional Patent Application Ser. No. 60/871,717, filed on Dec. 22, 2006. Each of the aforementioned related patent applications is herein incorporated by reference.

### BACKGROUND OF THE INVENTION

1. Field of the Invention

The present invention is related to interconnect technologies for back contact solar cells, particularly techniques to improve the efficiency and/or reduce the grid resistance of solar cell modules by minimizing or eliminating busbars and tabs.

2. Description of the Related Art

Note that the following discussion refers to a number of publications and references. Discussion of such publications herein is given for more complete background of the scientific principles and is not to be construed as an admission that such publications are prior art for patentability determination purposes.

### SUMMARY OF THE INVENTION

The present invention is a back contact solar cell module, the module comprising a plurality of back contact solar cells; a plurality of conductive interconnects, each interconnect extending the length of one or more solar cells and electrically connected to a plurality of bonding locations on the interior of a back surface of each of the one or more solar cells; and insulating material disposed between the interconnects and the one or more solar cells at locations other than the bonding locations; wherein the interconnects comprise a freeform structure at or near each of the bonding locations. The solar cells are preferably busbarless. The interconnect preferably comprises a metallic foil or ribbon having a thickness between approximately 1 mil and approximately 8 mils. The interconnect preferably comprises copper coated with a solderable metallic coating. The foil or ribbon was preferably stamped or die-cut into a final interconnect shape. The solid area of the interconnect preferably comprises an approximate shape selected from the group consisting of rectangle, triangle, and diamond. The freeform structure is optionally either exterior to a solid area of the interconnect and attached to an edge of the interconnect or attached to an edge of an opening disposed within a solid area of the interconnect. The insulating material is preferably laminated to the interconnect prior to assembly of the module and preferably comprises an EPE trilayer. At least a portion of the insulating material preferably melts during assembly of the solar cell, thereby melt bonding the interconnect to the solar cell. The insulating material optionally comprises a tackifier.

The present invention is also a method for assembling a solar cell module, the method comprising the steps of arranging a plurality of solar cells; disposing a plurality of conductive interconnects comprising a plurality of freeform structures on the solar cells, each interconnect extending across two or more solar cells; and heating the solar cells and interconnects, thereby soldering portions of the interconnects to bonding locations on the interiors of back surfaces of the two or more solar cells. The method preferably further comprises the step of laminating an insulator to the interconnects prior to the disposing step. The insulator is preferably not laminated to the portions of the interconnect to be soldered. The method preferably further comprises the step of stamping or die-cutting a final shape of the interconnect out of a metallic foil or ribbon. The method optionally further comprises the step of disposing an insulator on the solar cell prior to the step of disposing the interconnects on the solar cells, wherein the step of disposing an insulator preferably comprises a method selected from the group consisting of depositing, screen printing, inkjet printing, taping, laminating, and mechanically inserting a discrete insulator. The method preferably further comprises the step of melting an insulator disposed between the interconnects and the solar cells, the insulator not disposed at or near the bonding locations. The melting step optionally occurs during the heating step. The method preferably further comprises the step of the freeform structures accommodating stress induced during the heating step.

An object of the present invention is to reduce or eliminate the need for busbars and/or tabs in back-contact solar cells.

An advantage of the present invention is the reduction in series resistance over standard back-contact solar cells.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention. In the drawings:

FIG. 1 are schematic illustrations of back-contact cells with parallel interdigitated negative- and positive-polarity grid lines (i.e. interdigitated back-contact or IBC). FIG. 1A depicts currently used technology with busbars at the cell edge for collecting current and attaching electrical interconnects. FIG. 1B is an alternative design that has busbars at the edge and in the interior of the cell.

FIG. 2 are illustrations of an IBC cell with current extraction at the cell edge and with a smaller area for the busbar. FIG. 2A shows an IBC cell with no busbar, although a thin busbar at the cell edge may optionally be included for redundancy. FIG. 2B illustrates an IBC cell where the grid lines are made wider or flared at the end to facilitate connection of the electrical interconnects. FIG. 2C illustrates electrical interconnection of such cells using an interconnect (e.g. Sn-plated Cu ribbon) with many fine interconnection features (“combs”) to match the gridlines in the IBC cell. FIG. 2D illustrates a fine-comb Cu interconnect on a substrate (e.g. a flexible circuit or flex interconnect) to facilitate handling. FIG. 2E illustrates an IBC cell with an optional thin busbar and wire bonds for the electrical interconnect.

FIG. 3 are illustrations of an IBC cell with reduced-area interior busbars. The busbars have reduced geometries to reduce series resistance losses in the solar cell, while including wider regions (“pads”) for connection of the electrical interconnect (FIG. 3A). The interior busbar can subsequently be coated with an electrical insulator layer (FIG. 3B) to prevent shorting of the grids when the electrical interconnect, such as copper ribbon, is applied (FIG. 3C).

FIG. 4 depicts several offset island interconnect designs for busbarless or reduced busbar back-contact cells with interior current collection. The design allows for multiple current collection points with a tapered buss which takes into consideration the thermal mechanical stress associated with temperature cycle induced fatigue.

FIG. 5 shows various views of offset island interconnects connecting multiple solar cells.

FIG. 6A shows inset island interconnects of the present invention extending across multiple cells. FIGS. 6B and 6C show the difference between shorter and longer connection arms, respectively. FIGS. 6D and 6E show the difference between more and fewer connection arms, respectively.

FIG. 7A shows a variety of stamped inset and offset island interconnects of the present invention. FIG. 7B shows stress measurements of various stamped inset and offset island interconnects of the present invention.

FIG. 8 shows a braided interconnect of the present invention.

FIG. 9A is a schematic of a wire cloth material suitable for manufacturing interconnects, showing out of plane relief. FIG. 9B is a photograph of copper wire cloth. FIG. 9C shows a cell bussed with wire cloth comprising punched holes.

FIG. 10 depict an IBC cell with current extraction at the cell edges. The basic cell structure starts with parallel interdigitated gridlines (FIG. 4A). An insulator layer is preferably applied at the cell edges over the grid lines with openings that expose only one of the polarities at each edge (FIG. 4B). A conductive layer is deposited or printed that functions as the busbar and electrical interconnect area (FIG. 4C). The “+” signs illustrate where the metal layer makes electrical contact to the underlying gridline.

FIG. 11 are schematic illustrations of busbarless back-contact cells with interior current collection. The simplest cell structure starts with a busbarless IBC structure (FIG. 5A). An electrical insulator is preferably deposited over the gridlines with openings that expose only one of the polarities (FIG. 5B). An electrical interconnect (“copper ribbon” in illustration) can now be applied to connect only to the exposed polarity (FIG. 5C).

FIG. 12 show alternative interconnects. FIG. 6A shows a cell bussed with corrugated ribbon interconnects. FIG. 6B shows a corrugated ribbon illustrating out-of-plane stress relief. FIG. 6C shows a busbarless solar cell with flex circuits embodying various finger geometries.

FIG. 13 are schematic illustrations of a busbarless back-contact cell interconnected with a laminated wire bonding process. The simplest cell starts with an IBC cell (FIG. 7A). Electrical insulator pads are preferably printed so that the wires will only interconnect to one polarity (FIG. 7B). Wires coated with an appropriate low-temperature alloy can then be bonded to the exposed grid lines using, for example, a lamination process (FIG. 7C).

FIG. 14 is a schematic illustration of a busbarless back-contact cell with isolated contacting or receptor points. They are preferably interconnected during a wire lamination process; or, alternatively, the interconnects may comprise a separate deposited metal layer that does not electrically connect to the solar cell.

### DETAILED DESCRIPTION

### Best Modes for Carrying Out the Invention

The present invention is directed to techniques for interconnecting back contact solar cells and modules. The emitter wrap-through (EWT) solar is one type of a back-contact solar cell structure. It features higher efficiency than standard cells due to elimination of the current-collection grid lines on the front surface that would otherwise reduce optical absorption. The current-collection junction (“emitter”) on the front surface is wrapped through holes in the silicon substrate during the emitter diffusion. A related back-contact cell structure (“back-junction cell”), which also does not have any grids on the front surface, has both the negative- and positive-polarity current-collection junctions located on the rear surface. Another related back-contact cell structure (“metallization wrap through” or MWT) wraps the metal grid from the front to the rear surface through holes.

Silicon solar cells are electrically connected together to form an electrical circuit for power production. Interconnection of conventional silicon solar cells with straight Cu flat ribbon introduces substantial losses—around 2.5 to 3% electrical power loss due to resistance and another 3 to 5% loss due to reflected light. Conventional front-grid solar cells can not use Cu interconnects with larger cross sections because wider ribbon introduces larger optical losses while thicker ribbon is too stiff and introduces stress. However, back contact solar cells use a different geometry for interconnecting the solar cells into electrical circuits compared to conventional cells with front-surface grids. The optical losses are eliminated and the electrical losses introduced by the interconnect can be made very small since the size of the interconnect is not constrained by optical losses like in conventional front-grid solar cells. Optimization of the current collection grid on the back-contact solar cell and of the interconnect simultaneously provides for lower series resistance losses and higher efficiency, while optimization of the interconnect to minimize stress enables long product lifetime.

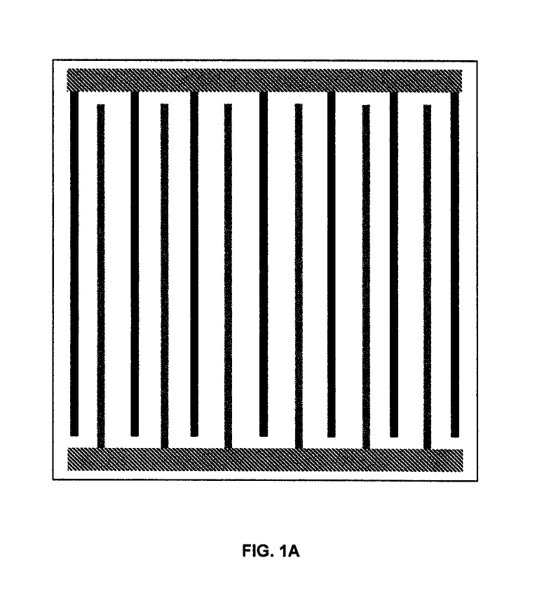

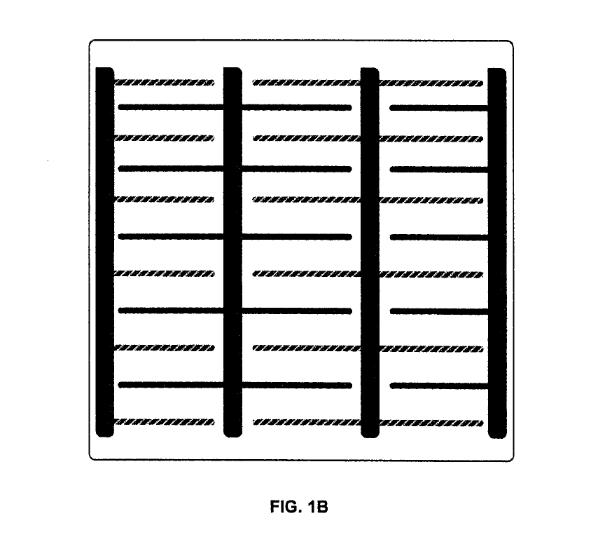

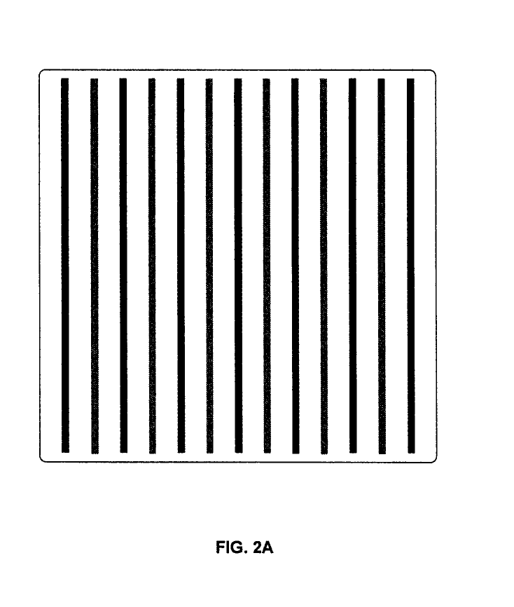

A simple geometry for the current-collection grid EWT and back-junction back-contact solar cell uses interdigitated negative- and positive-polarity grids (FIG. 1A). Current is extracted to the two busbars with the interdigitated grid lines. The busbars can include areas for attaching electrodes (“tabs”) for assembly of the solar cells in an electrical circuit. These tabs must be large enough to accommodate alignment tolerances in the assembly tools.

There are two problems with this grid geometry. First, the regions of the solar cell above the busbars and tabs and at the edges of the solar cell have higher series resistance due to a longer path length for collection of the current. This loss can be reduced by minimizing the area of the busbar, although a minimum area is required to minimize the resistance in the busbar and for attachment of the electrodes.

The second problem with this grid geometry is the series resistance of the grid lines. The current must travel the full length of the cell even though the current is only extracted from the cell edges, so the grid must be made very conductive, typically by using a thick metal. Solar cells commonly use silver (Ag) applied by screen printing for the conductive grid, which is very expensive when a thick conductor is required. Screen-printed Ag grids are also fired at a high temperature, which can introduce stress in thin silicon solar cells. The grid lines can be reduced in length by using additional busbars and tabbing points in the interior of the cell (FIG. 1B). The busbar width in this example is wider than the Cu interconnect to prevent electrical shorting with opposite polarity grids. However, this geometry introduces additional series resistance losses due to the additional busbar, tab, and interconnect area as described above. A straight Cu ribbon interconnect bonded across the length of a back-contact cell with the geometry of FIG. 1B would also introduce significant stress due to the difference in thermal expansion coefficients of the silicon solar cell and Cu interconnect. Conventional cells with front-surface grids have Cu interconnects soldered on front and rear surfaces that balance the stress, which helps reduce the overall stress. The electrical connection between the solar cell and the interconnect (typically a solder bond) may therefore experience more fatigue for back-contact relative to front-grid solar cells. Therefore, the interconnect design for back-contact cells must address single sided, solder bond related issues as well as stress and series resistance considerations.

The losses due to the busbars and grid lines can be reduced by new cell geometries that significantly reduce the area covered by the busbar. The losses in the interconnect can be reduced by new interconnect designs that address cell bowing, solder pad stress, and interconnect fatigue. The “busbarless” back-contact cell eliminates the busbar losses entirely by contacting the current collection grids individually.

Reduced Busbar with Current Extracted at Cell Edge

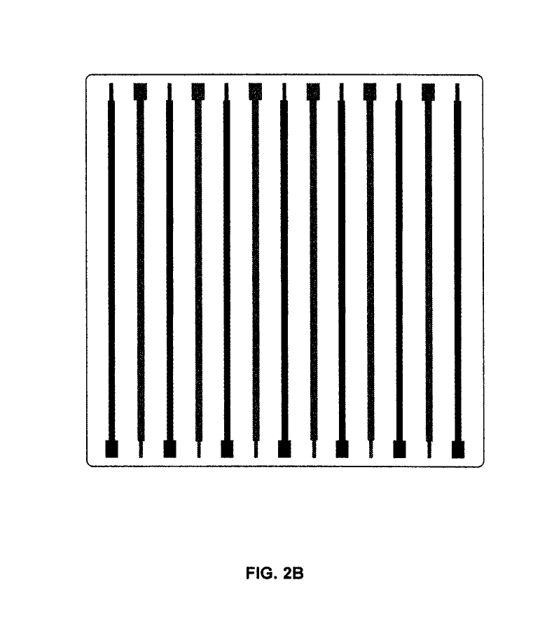

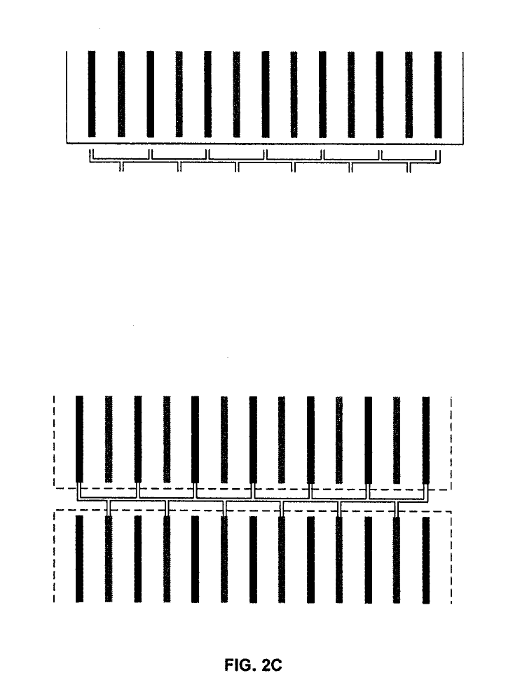

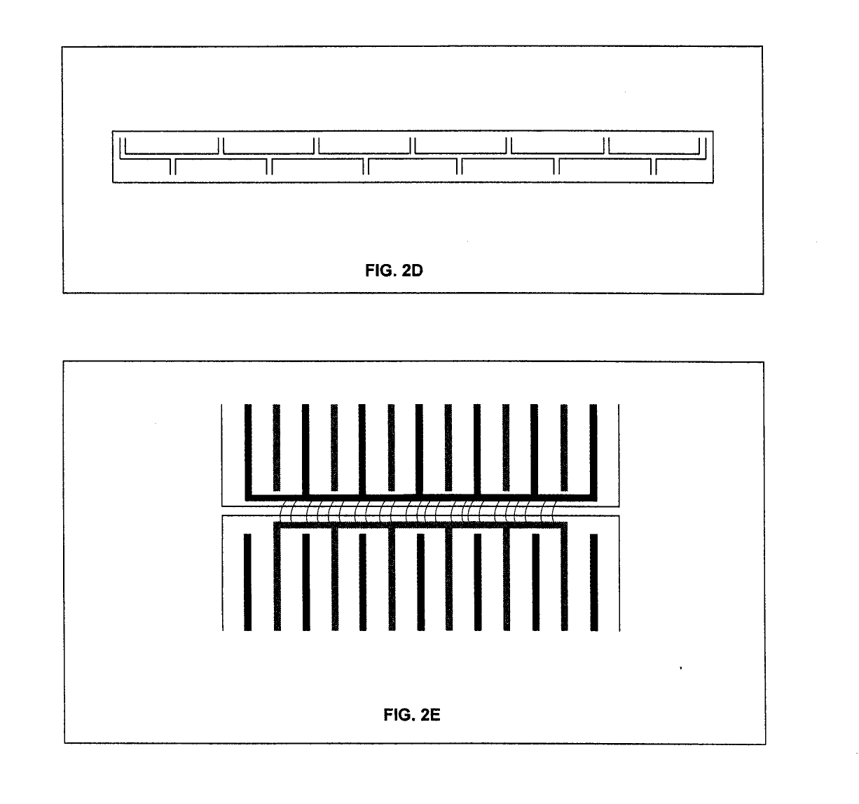

A first embodiment of the present invention reduces the busbar and tabbing pad dimensions greatly while using the standard interdigitated grid geometry and current extraction at the cell edge. The busbar must have sufficient conductivity to carry current with minimal resistance losses to the points where current is extracted. The busbar conductivity requirement, and hence area, is reduced by increasing the number of points where current is extracted. This approach also preferably utilizes interconnect technologies that use much less area for the electrical attachment. Although this geometry greatly reduces losses due to the busbar, it still requires a thick grid line since current is extracted at the edge of the cell. The geometry can completely eliminate the busbars if the electrodes contact each individual grid line (FIG. 2A). The grid lines are optionally wider or flared at the cell edge, for example forming pads, to facilitate the interconnection (FIG. 2B). Nevertheless, a small busbar is often preferred to increase redundancy between grid lines.

The interconnect (electrodes) between the cells preferably makes contact at many points, and can be accomplished in a number of ways, including but not limited to:
Stamped Sn-plated Cu ribbon with many fine electrodes. The fine electrodes are necessary to make the many interconnection points, which might be difficult to handle when using automated assembly tools (FIG. 2C). The fine electrodes are preferably not collinear, which helps minimize stress.
Patterned Sn-plated Cu circuit on a flexible substrate (“flex circuit”) (FIG. 2D). This element may be easier to handle by automated assembly tools than the individual Cu ribbons with fine electrodes.
Wire bonding between cells (FIG. 2E). Wire bonding is a well known technique from the electronics industry for packaging semiconductor chips. An additional advantage of wire bonding is that the thin wires are nearly invisible in the photovoltaic module packaging (improved aesthetics) and introduce very little stress.

These electrodes can be electrically attached using well-known techniques such as soldering, applying conductive adhesives, or welding.

Reduced Busbar with Current Extracted from Cell Interior

The busbar and tabbing pads may optionally be positioned both at the cell edges and in the interior of the cell. An example of this cell geometry is shown in FIG. 1B. An advantage of this geometry compared to current extraction at cell edges is the reduced grid line length—the grid resistance and metal area is greatly reduced with the shorter grid lines. Although not required, FIG. 1B shows the busbars wider than the electrical interconnect between cells so that the electrodes do not short the negative and positive polarities. The electrodes typically comprise flat copper ribbon with a width of 2 to 3 mm. The problem with this geometry is that there is a significant loss due to the high resistance in the regions above the busbar as well as large solder pad stress.

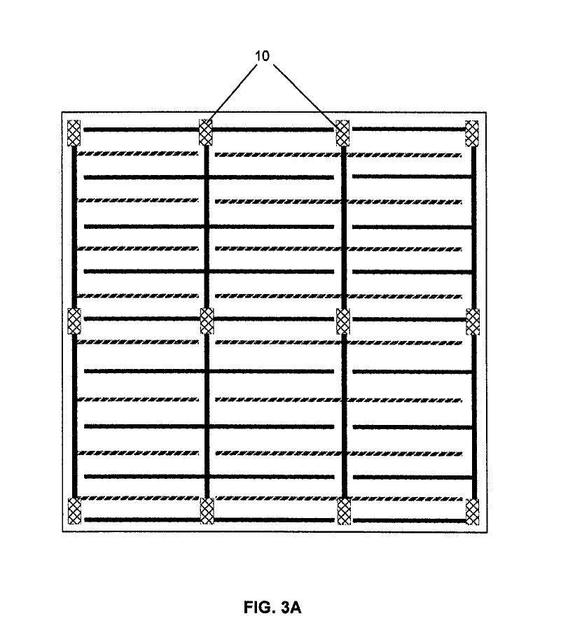

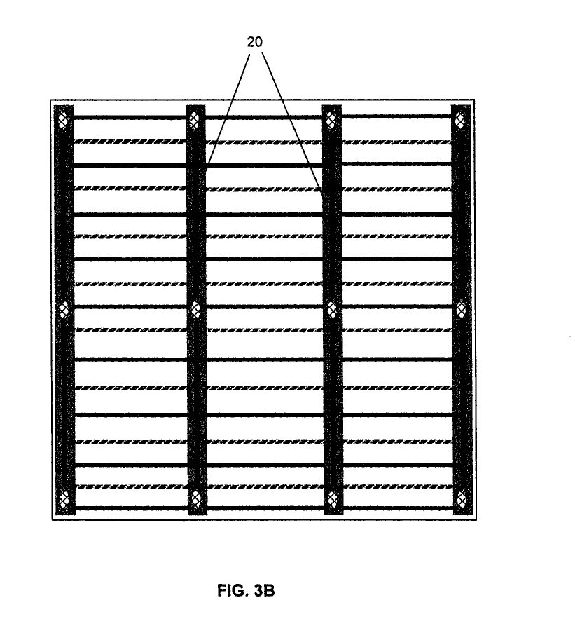

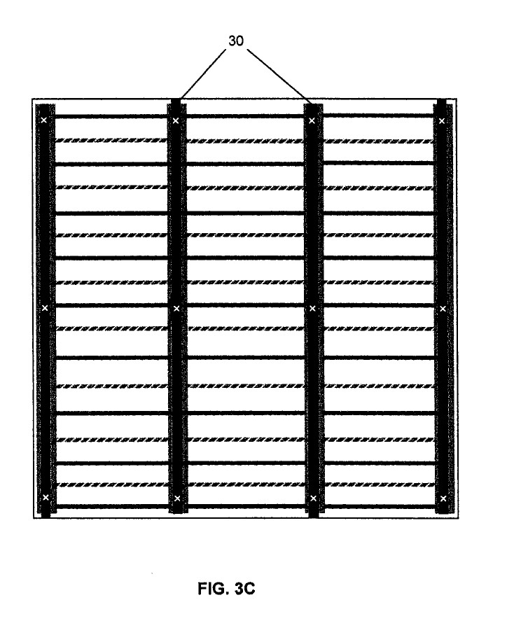

These losses can be reduced by reducing the area of the busbars. The busbar width can be made thin since current is extracted at many points, resulting in less current in each region of the busbar. Pads 10 are preferably disposed along the busbar to facilitate the electrical interconnection (FIG. 3A). However, the copper electrode will now typically be wider than the busbar and could short the negative and positive polarities. This can be prevented by adding insulator 20 around the busbar to prevent electrical interconnect 30 from contacting the solar cell gridlines (FIGS. 3B and 3C), or alternatively by distancing the gridlines of opposite polarity from the busbar and keeping the busbar ribbon narrow enough such that shorting between the polarities does not occur. Each “x” in FIG. 3C denotes a spot where the interconnect is electrically connected to the underlying gridline.

Rather than a straight copper ribbon wire, the interconnect may comprise a pattern with features to minimize stress introduced to the cell (i.e., bow) or to the electrical bond between the interconnect and the cell (i.e., fatigue of the joint). The thin copper pattern layer could also-be integrated on a flexible ribbon substrate (“flex circuit”) to facilitate handling. The Cu interconnect or flex circuit could include the patterned insulator layer over the copper layer, which would eliminate the need for a patterned insulator on the solar cell. The Cu could optionally include a thin Sn or other solder alloy layer to ease electrical assembly. The interconnect may be electrically attached with conductive adhesives, solder bond, welding, or other methods. Various examples of these approaches are presented.

### Interconnect Designs

Important issues for design of the interconnect are to reduce or minimize (a) stress on the cell, (b) stress on the electrical joint, (c) series resistance, and (d) cost. The interconnect is preferably designed to isolate the stress in small geometric features of the interconnect (in-plane or out-of-plane stress-relief loops), or to use alternative interconnect materials with greater inherent flexibility.

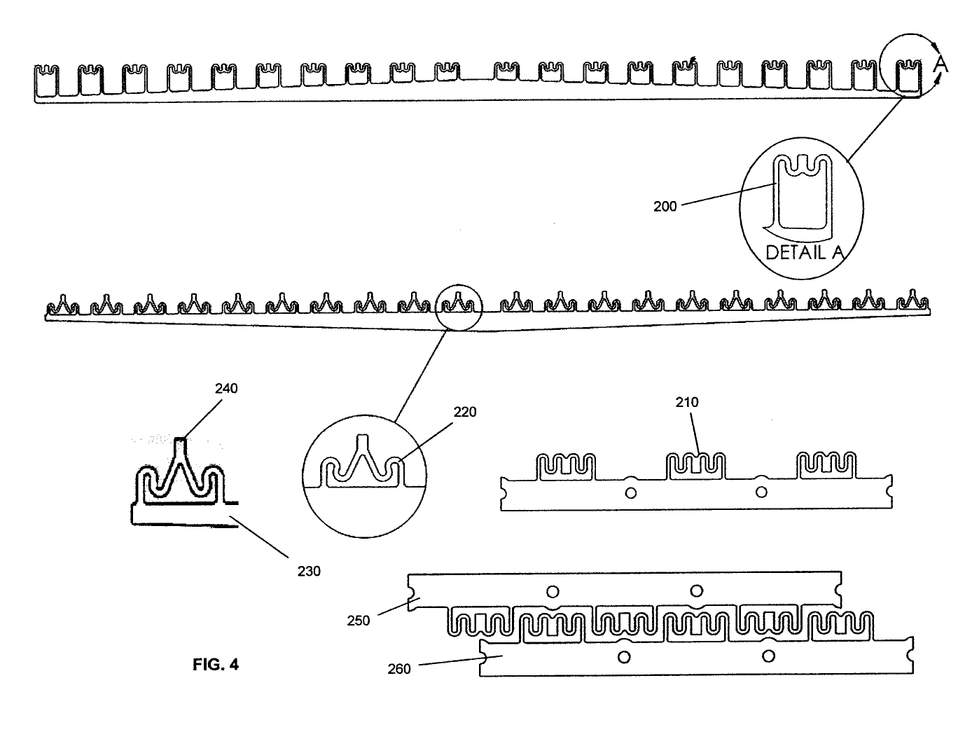

A variety of novel interconnects may be used in conjunction with the embodiments of the present invention disclosed herein. The interconnect preferably comprises a flat copper ribbon, preferably comprising a metallic coating, such as Sn or Sn/Ag for solderability. The interconnect could optionally include a dielectric layer such as described above. This concept is different from such ideas as a flex circuit in that the dielectric is preferably prelaminated to the interconnect and stamped out or die-cut into a roll. FIG. 4 shows interconnects comprising a plurality of freeforms 200, 210, 220, in this embodiment called “offset islands”. This design enables the use of a prelaminated interconnect whereby bonding area 240, which bonds to the electrical contact (e.g. solder pad or solder bond) on the solar cell, is preferably free of dielectric coating 230. Dielectric coating 230 preferably electrically isolates the remainder of the interconnect from the solar cell. Alternatively a strip of the insulator construction may be placed between the interconnect and solar cell as a discrete layer, typically applied directly to the solar cell. The electrical connection may be achieved by conductive adhesives, solder bond, welding, or other methods currently known to the public. The interconnect is preferably tapered on either end as shown. Because current increases linearly along the length of the interconnect, a tapered interconnect reduces the total mass of Cu or other metal (thereby minimizing stress and cost), while having an increased cross section of Cu as the current increases. FIG. 4 also shows two interleaved or nested interconnects 250 and 260 prior to removal from a Cu sheet, such as by stamping; thus two strips of interconnect material can be stamped out in one process, conserving raw material.

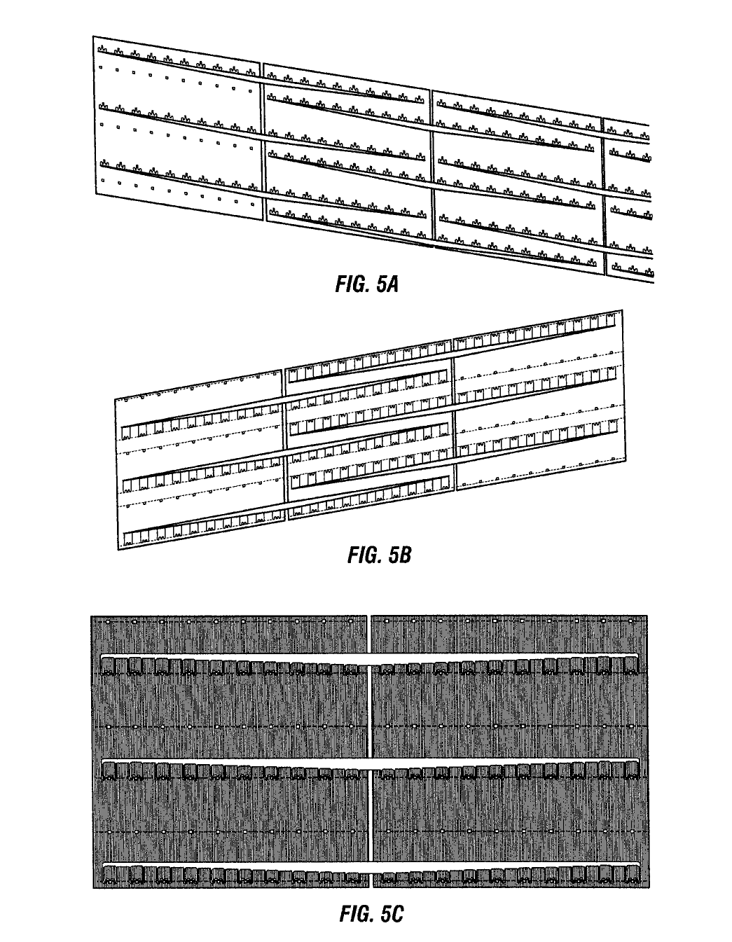

Stress relief in this example is provided by the in-plane stress relief freeform structures or loops; i.e, the small symmetrical “u” features near the solder pad area. The stress is preferably shared between the two supporting “u” features on either side of the solder pad area. The “offset island” interconnect design preferably enjoys the advantages of reduced series resistance by enabling use of copper thicknesses greater than about 0.005″ without adversely affecting solder bond stress or stress relief features; reduced bowing of the solar cell after solder reflow; reduced thermal fatigue and cracking of the copper interconnect; and solder pad stress is maintained at an acceptable level. The interconnect thickness is preferably between approximately 5 mils and approximately 6 mils, but optionally may be between approximately 1 mil and about 8 mils, although it could be 10 mils or more. FIG. 5 shows a series of cells interconnected with offset island-type interconnects. Thus the interconnects preferably extend the length of a plurality of solar cells.

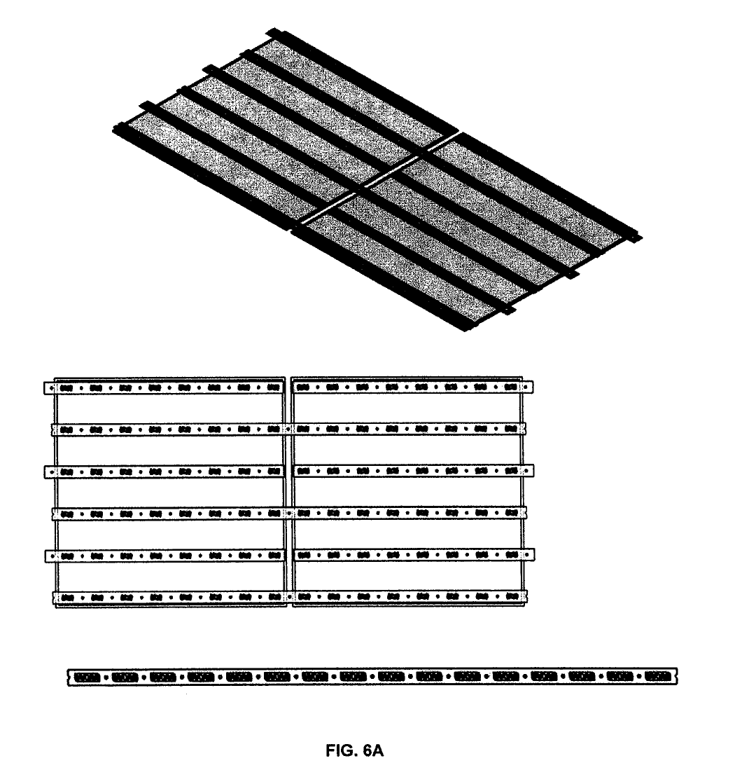

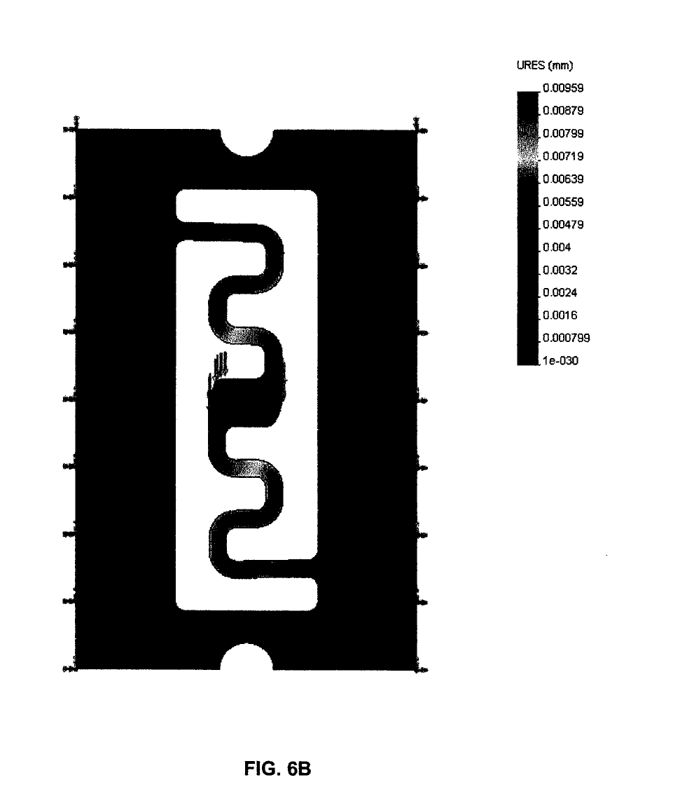

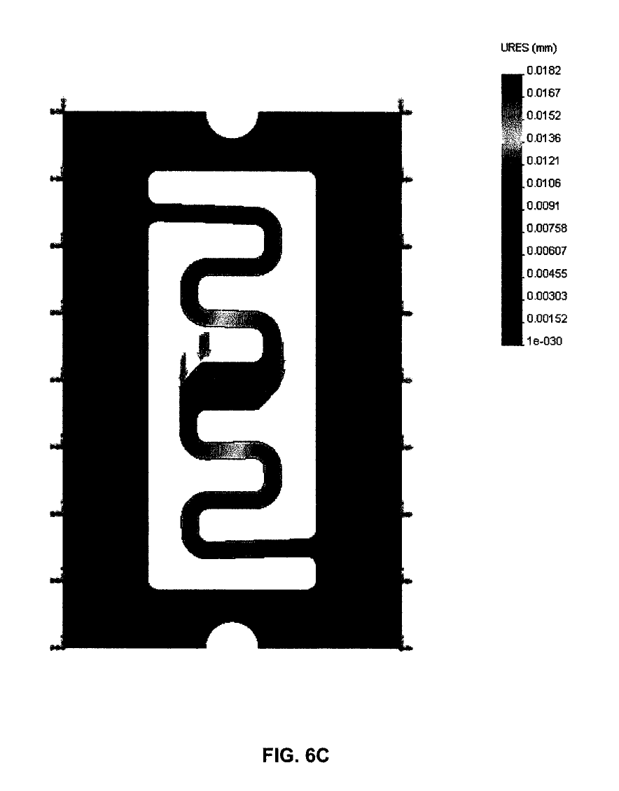

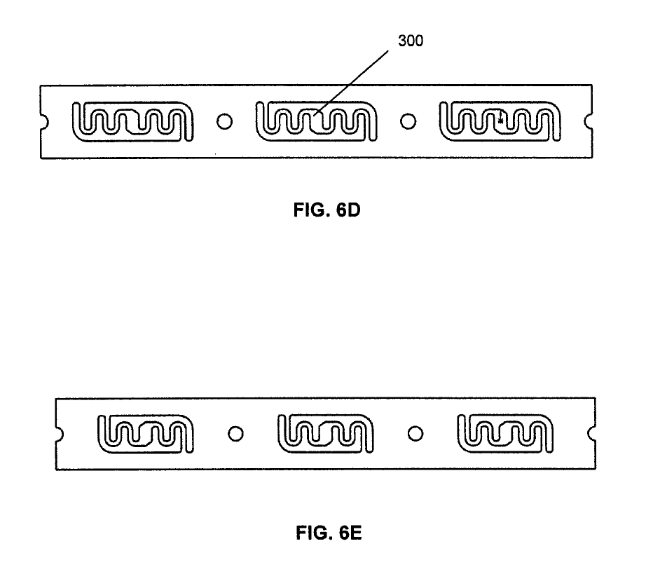

An alternate stamped interconnect design, shown in FIG. 6, comprises a plurality of “inset islands” 300 within the width of a copper ribbon; this design also reduces stress while maintaining a straight edge profile, thus ensuring greater compatibility with industry standard cell stringing equipment, which is typically designed for handling solid ribbon of various widths. Offset and inset here refer to the alignment with the major bus. FIG. 6A shows inset island interconnects extending across multiple solar cells. Small arms 310, which preferably are approximately perpendicular to the interconnect length, preferably provide flexure to absorb stress. Longer arms, shown in the FIG. 6C versus FIG. 6B, typically provide more stress relief but require wider stock material. Increasing the number of arms (as shown in the FIG. 6D over the fewer arms of FIG. 6E) provides more flexure without requiring wider material. Stress relief may also be improved by reducing arm widths. The arm width is preferably between about 0.1 mm to about 1 mm and more preferably from about 0.1 to about 0.4 mm. Tooling geometry typically limits the minimum dimensions of stress relieving features which can be stamped out in high volume.

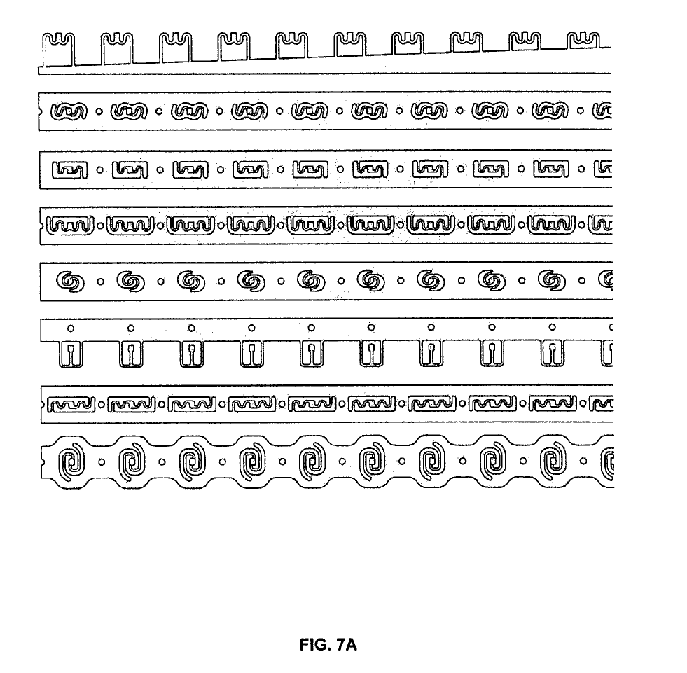

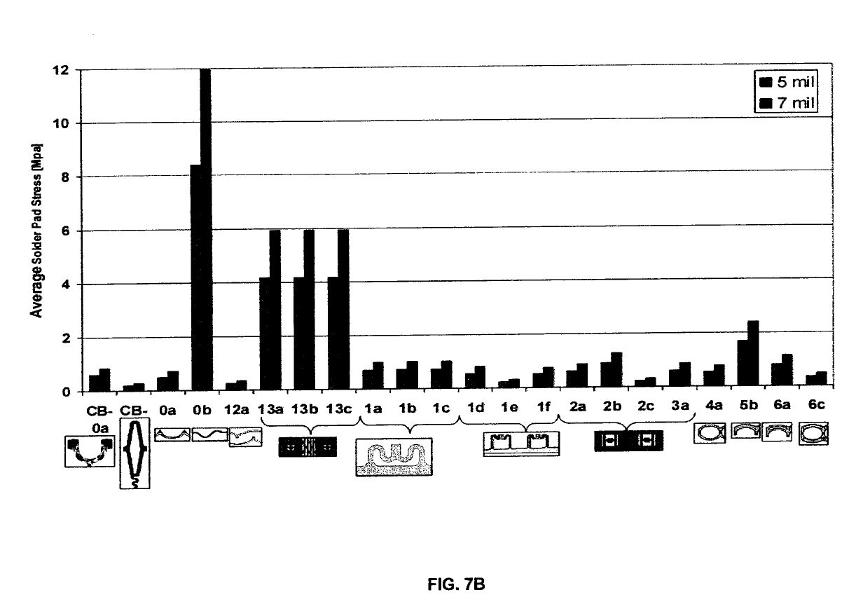

A variety of other offset or inset island geometries which can achieve similar stress relief is shown in FIG. 7A. Some of these geometries, and others, were tested for solder pad stress for two different copper thicknesses. The results are shown in FIG. 7B. This analysis takes into consideration the thermal cyclic fatigue caused by temperature cycling induced stress as defined by IEC 61215. As used throughout the specification and claims, “freeform structure” means a thin stress relieving feature, structure, strand, wire, extension, loop, or the like which is attached (preferably although not always in two locations, one at each end of the structure) to the bulk (or solid area) of the interconnect, as shown in FIGS. 4-7.

Another advantage of the offset or inset island design is improved management of solder reflow induced bow to the cell. The manufacturing of all back contact cells requires interconnection to be performed on one surface. This places a large demand on the connector design to manage thermal mechanical stress for long term reliability as well as bow management for manufacturability. Excessive bow typically introduces large variations in material handling of the cell, string, and subsequent lamination process. These variations typically resulting in reduced machine throughput and increased costs to the module. The “Island” design comprises separating the solder bonding area from the larger buss which carries the current, thereby reducing bow and increasing stress relief.

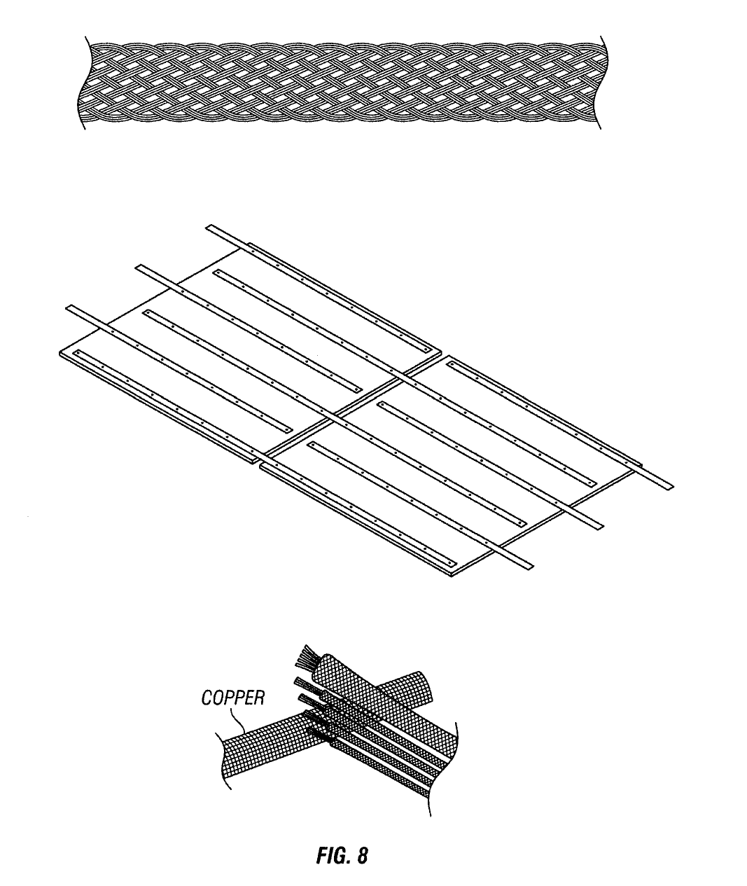

An alternative interconnect, shown in FIG. 8, comprises conductive braid preferably comprising many fine strands which can flex in multiple directions. The braid may optionally be sized for an area wider than the bond pads, thus reducing the alignment requirements during application, since only a few strands preferably need to be bonded to the cell at any given pad to carry the current a short distance to the braid bulk. Tension may be mechanically controlled during bonding to reduce initial stress as well as packing density, which can affect infiltration of encapsulating materials.

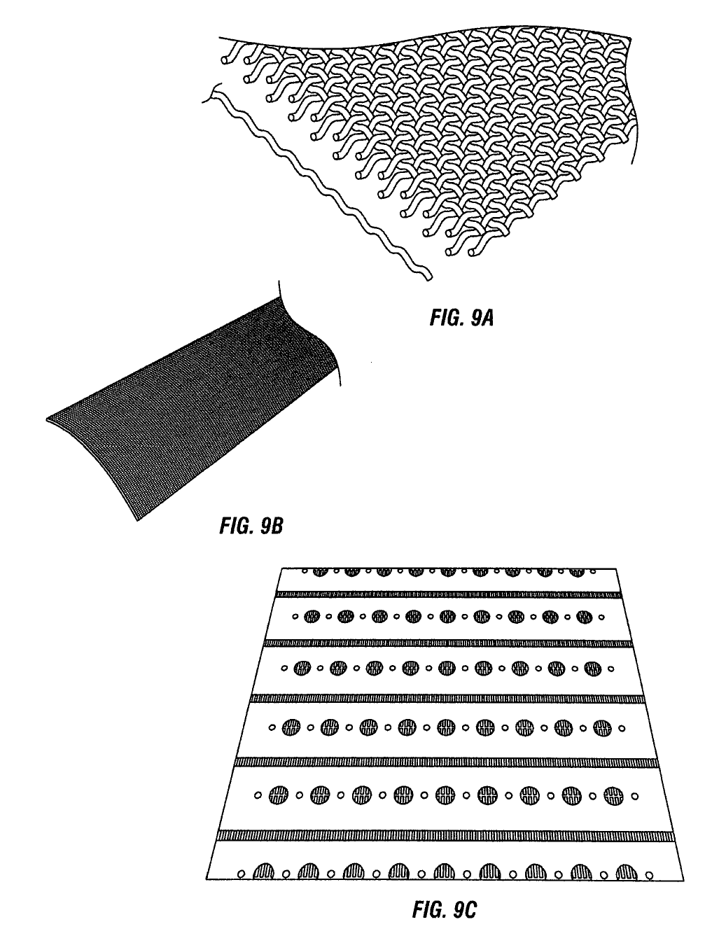

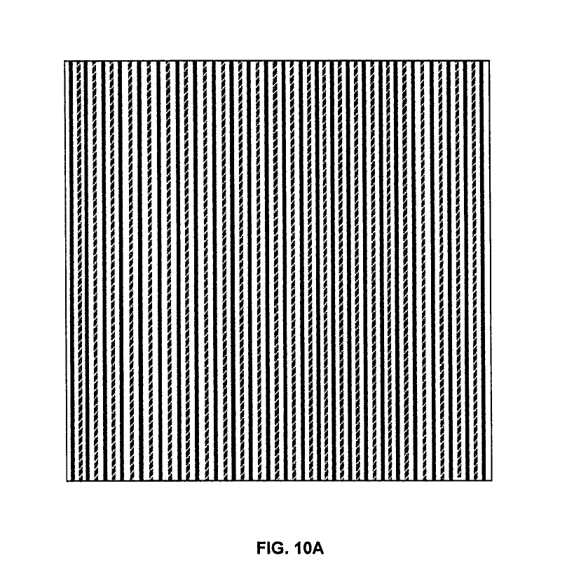

Conductive wire cloth or screen, as shown in FIG. 9, also has innate stress relieving properties; it comprises many conductive strands much smaller than conventional ribbon (typically 0.002″ to 0.020″ diameter), with each strand having a multitude of bends perpendicular to the cell plane providing out-of-plane stress relief (FIG. 9A). Tension can be controlled during manufacture to create higher peaks and valleys, resulting in better strain absorbing capabilities; each peak and valley is preferably supported by a cross thread, preventing flattening during lamination cycles. The mesh can be oriented at an offset angle from the interconnect direction on the cell so that no single strand is soldered to multiple bond pads; alternatively, slots or holes can be punched at intervals between bond pad locations to break strands along the interconnect length, as shown in FIG. 9C, thereby improving stress relief. In this case, the perpendicular strands preferably bring current from the pad to the continuous bulk.

The wire cloth mesh count may be selected for a balance of conductivity, stress relief, and encapsulant infiltration. Materials such as an elastomeric fiber could be used for supporting cross threads, which would preferably allow threads in the interconnect direction to expand and contract more freely. Alternatively, a thermoplastic or thermoset fiber could also be used, which would reflow during encapsulation, leaving many fine threads running in the interconnect direction. Various types of weave such as Twill Square, Plain Dutch, or Twill Dutch of varying densities can provide tighter packing of strands and improved conductivity. The wire diameter may be chosen to minimize series resistance and stress. Handling of wire cloth in a stringing tool may be accomplished though mechanical gripping or piercing, or alternatively, vacuum handling features can be added to fill in the mesh apertures in select locations. A dielectric could also be patterned on the wire cloth interconnect to provide adequate vacuum handling. Bare copper has known compatibility issues with EVA and is typically controlled by tin coating of the copper, which also has the advantage of being solderable. Wire cloth provides an advantage in this regard since the area of copper left exposed along the interconnect perimeter is much smaller than with a solid stamped interconnect.

A wire mesh interconnect may also allow for reducing the area of the individual interconnect point by providing a larger number of smaller bonding points (i.e., wires), thereby allowing for reduced area for the busbar and bonding pads on the solar cell. The busbar and bonding pads reduce the efficiency of the solar cell, so reducing the area of these parts of the solar cell increases the efficiency of the solar cell.

Metallic meshes are available with different mesh counts (wires per inch) and wire diameters. The wires in the mesh can also be bonded via calendering so that wires do not separate from or within the mesh. Calendered meshes are typically stiffer, so the calendaring amount also needs to be optimized for stress and physical integrity of the mesh. Aesthetically, wire mesh is likely to be less apparent to the viewer of the photovoltaic module, thus providing a more pleasing appearance.

The interconnect material may alternatively comprise other porous materials, such as expanded metal mesh or other like materials.

### Insulator

The insulator used to isolate the interconnect from the solar cell may comprise any material, whether an inorganic or organic compound, including but not limited to a dielectric, a crossover dielectric, EVA, polyester, polyamid (such as Kapton) aluminum oxide or solder mask. Aluminum oxide or a like material disadvantageously requires a high temperature firing step, usually 700° C. higher, which when combined with silver firing may cause shunting of the solar cell. This problem can be addressed by co-firing of both silver and crossover dielectric but material compatibility is a major issue in this case.

The insulator may be in tape form or a discrete layer between the interconnect and the cell, which can be applied via lamination or other methods known in the art. The insulator may alternatively be deposited on the solar cell by printing techniques such as screen printing, ink-jet printing, or other patterned deposition techniques. Due to the relatively large geometries involved, the insulator may comprise an adhesive tape, for example a dielectric tape such as PET (polyethylene terephthalate), with an adhesive, or glass fiber tape. As described above, for offset or inset island interconnects the insulator is preferably laminated directly to the interconnect. The use of a construction comprising a tri-layer of EVA/dielectric/EVA, commonly known as EPE (the “P” stands for polyester or PET as the dielectric), is preferred due to its long term robustness, reliability, and compatibility with the encapsulant. EVA is Ethylene Vinyl Acetate. The tri-layer preferably has a total thickness of between approximately 0.0005″ and approximately 0.010″, and more preferably between approximately 0.001″ and approximately 0.005″, and most preferably approximately 0.003″. Each EVA layer preferably has a thickness of between approximately 0.0005″ and approximately 0.003″, and more preferably approximately 0.001″. The dielectric layer preferably has a thickness of between approximately 0.0005″ and approximately 0.002″, and more preferably approximately 0.001″. Other high performance plastics such as PEN, Polyimide, or PPS may substitute for the dielectric. The EVA layers can be substituted with an olefin or ionomer based encapsulant. The EVA may comprise a thermoplastic or alternatively a thermoset, which does not ordinarily require the use of a UV protection package or the addition of a UV Absorber or hindered amine light stabilizer (HALS), but typically comprises an adhesion promoting additive such as an aminosilane.

The tri-layer construction preferably is able to survive solder reflow temperatures and eases registration of the interconnect. It also preferably provides mechanical support by melt bonding reliably to the solar cell interface and the interconnect after lamination. That is, the EVA preferably melts and fills gaps between the connector and the solar cell. A tackifier may be added to the EVA layers to improve registration to the interconnect and the solar cell. The tackifier content is preferably between approximately 10% and approximately 80%, and more preferably between approximately 10% and about 15% for ease of manufacturability. The tackifier may also be added to one or more discrete location around the cut outs (typically, the locations of the solder bond, or the electrical connection between the interconnect and the solar cell) to maintain a bondline to prevent excess reflow during soldering.

The tri-layer is typically constructed via extrusion of EVA onto PET with a second extrusion coating applying the second EVA layer onto the dielectric. The construction is not limited to three layers, but preferably provides a melt bondable layer. For example, the construction may comprise EVA/PET/EVA/PET/EVA layers, or the like, where the PET and/or EVA can be substituted with similar materials as discussed above. This type of insulator construction is typically applied on the buss of the cell with holes properly punched into the construction to expose the polarities as required. The insulator is alternatively prelaminated onto a freeform interconnect, such as discussed below, for ease of handling, specifically minimizing or eliminating handling of the trilayer. The dielectric may also be pigmented with a reflective coating such as TiO₂ to allow photons which pass through the cell to be absorbed on a second pass.

Reduced Busbar with Edge Extraction and Interlayer Dielectric

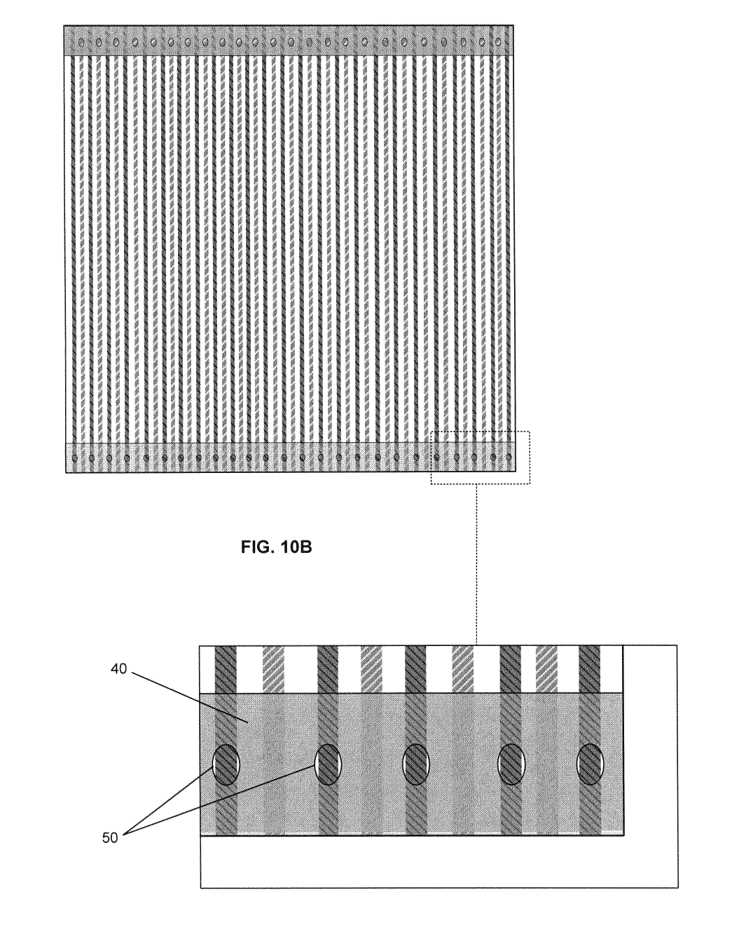

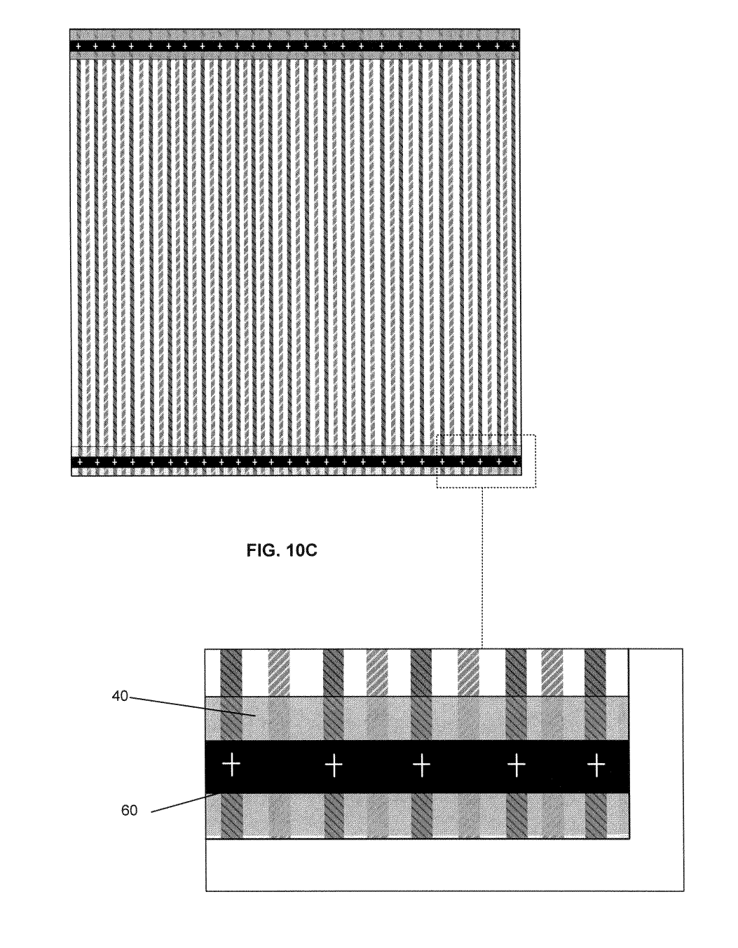

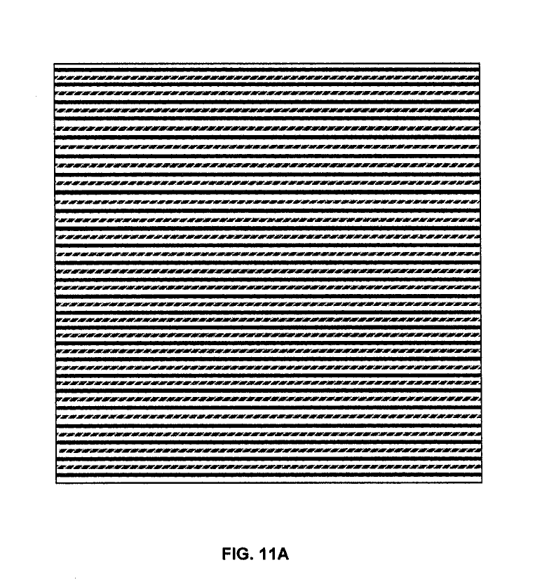

The losses due to the busbars and the tabbing pads in an edge-extraction geometry can be greatly reduced by placing the busbar on an insulator. The cell design preferably comprises parallel negative and positive polarity grids that preferably run the full length of the solar cell to maximize current collection (FIG. 10A). Insulator 40 is preferably deposited over the gridlines at each collection edge of the cell; insulator 40 preferably comprises openings 50 only over one of the polarities at each edge (FIG. 10B). Next, conductive material 60, preferably comprising a metal or alloy, is preferably deposited over the patterned dielectric to provide further conductance and a large area for attaching the electrical interconnects (FIG. 10C). This metal makes electrical contact to the grid lines through the openings at each location marked by a cross. The metal deposition is preferably compatible with the physical properties of the insulator. Examples are given below for the insulator and overlying busbar process. An advantage of this approach compared to the edge extraction embodiment above is that a larger geometry can be used for the tabs, which makes assembly of the solar cells into an electrical circuit easier to automate.

Busbarless EWT Cells with Interior Current Extraction

The required metal thickness and the grid resistance can be greatly reduced by extracting the current from multiple points along the interior of the cell rather than at only the edges of the cell. While busbars and tabbing pads could also be located in the interior of the cell, these reduce efficiency for the previously mentioned reasons. For these reasons, it is preferred to eliminate the busbars completely.

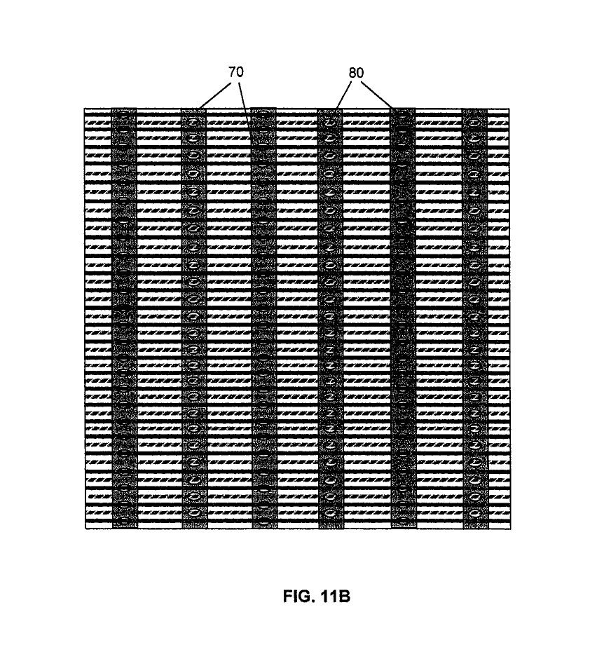

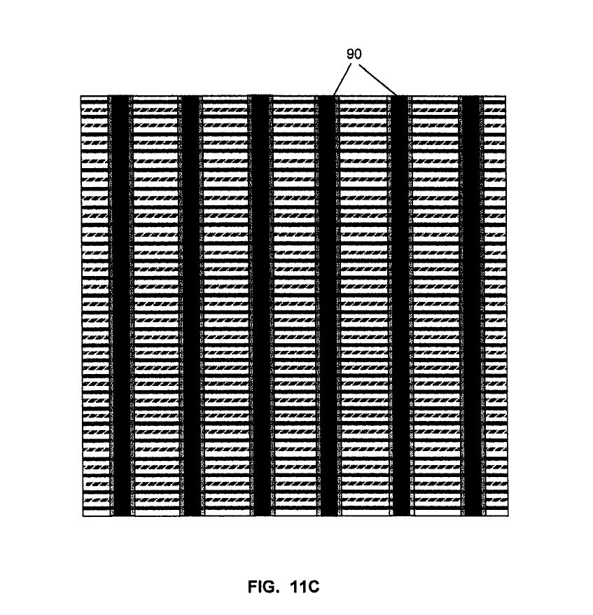

A simple geometry for the contacting metal and current-collection grid comprises parallel grid lines (FIG. 11A). In this embodiment, the electrical interconnect preferably connects to every gridline while not contacting the opposite polarity. Hence, electrical insulator 70 is preferably disposed on the gridlines to prevent shorting of the cell. The negative (“N”) and positive (“P”) grids preferably include intermittent regions (“pads”) with width greater than the gridline in order to facilitate the electrical interconnection. The insulator may optionally be applied directly to the solar cell by a patterned deposition technique such as screen printing or ink-jet printing. The insulator is preferably as described above, or alternatively may be deposited in a pattern over the grid lines exposing only the polarity that is to be contacted by the corresponding electrical interconnect, such as through openings 80, as shown in FIG. 11B. Each electrical interconnect contacts only, and preferably all, of the grid lines of a given polarity. The electrical interconnect may comprise copper ribbon wire 90, as shown in FIG. 11C, or alternatively a freeform interconnect, which may comprise small geometric features for stress reduction and/or may have lower resistance and greater manufacturing efficiency. The interconnect may alternatively comprise a flex circuit, which may have certain advantages for manufacturing efficiency. The electrical interconnect may be attached by means known in the art, including but not limited to soldering, sintering of low temperature powder, or using conductive adhesives.

A conductive layer can be deposited in a pattern over the insulator rather than the copper ribbon of FIG. 11C. This conductive layer effectively functions as a busbar and provides a broad area for the electrical attachment of the electrical interconnect, but is substantially electrically isolated from the solar cell and is therefore not a loss to the solar cell. The conductive layer preferably has the capability of being deposited and processed at a sufficiently low temperature to be compatible with the insulator. The conductive layer preferably comprises a metal or alloy, and may optionally comprise a composite of metal particles with binders, such as oxide frit (e.g. metal inks such as Ag screen-printed paste) or organic binders (e.g. conductive adhesives). Alternatively, the conductive material may comprise a nanoparticle metal ink that sinters at low temperatures. Methods for depositing the conductive layer include but are not limited to screen printing, ink-jet printing, and shadow mask thin-film deposition.

The interconnect, such as a copper ribbon wire or flex circuit, may optionally comprise a patterned insulator, thus eliminating the need for a patterned insulator on the solar cell. Alternatively, an interlayer dielectric (ILD), crossover dielectric, or an insulator layer between layers with electrical conductors may be employed. This approach can result in small contact areas and very low series resistance, since the metal conductive layer and interconnect can have an arbitrary geometry.

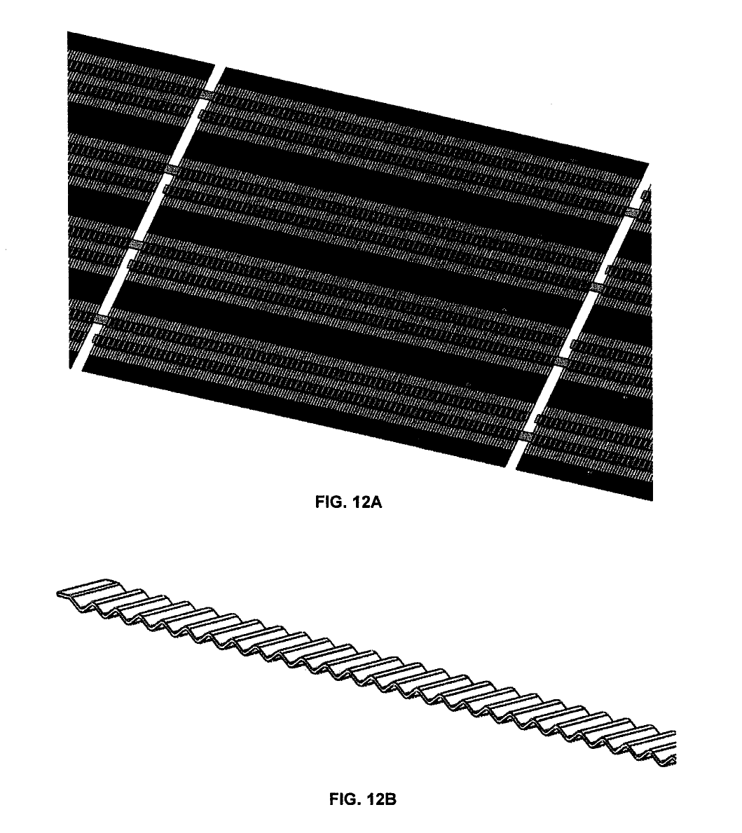

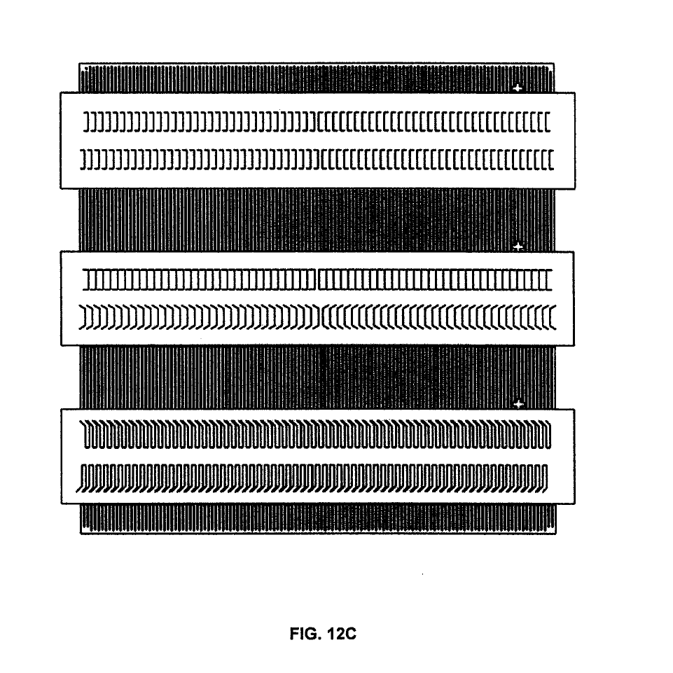

One embodiment of a busbarless interconnect comprises a flat conductive ribbon which is embossed or corrugated, preferably with a pitch matched to that of like polarity gridlines as shown in FIGS. 12A and 12B. An alternative approach, shown in FIG. 12C, is to make small cuts in the interconnect material, for example flat copper ribbon or flex circuit interconnects, leaving fingers preferably spaced at the same pitch as alternating polarities. Alternatively, the conductive braid, conductive wire cloth, or other interconnects described above may be employed.

### Wire Lamination Interconnect or Grid

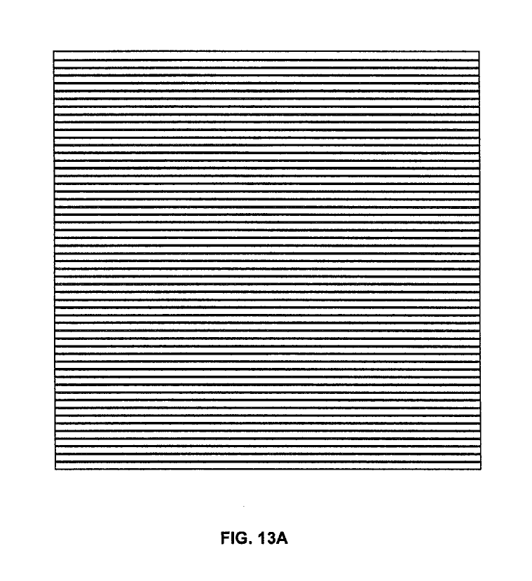

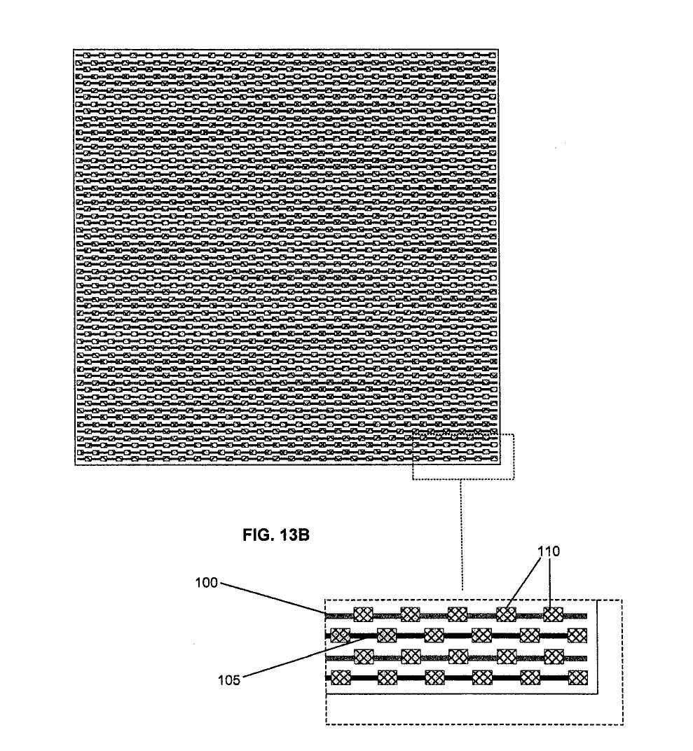

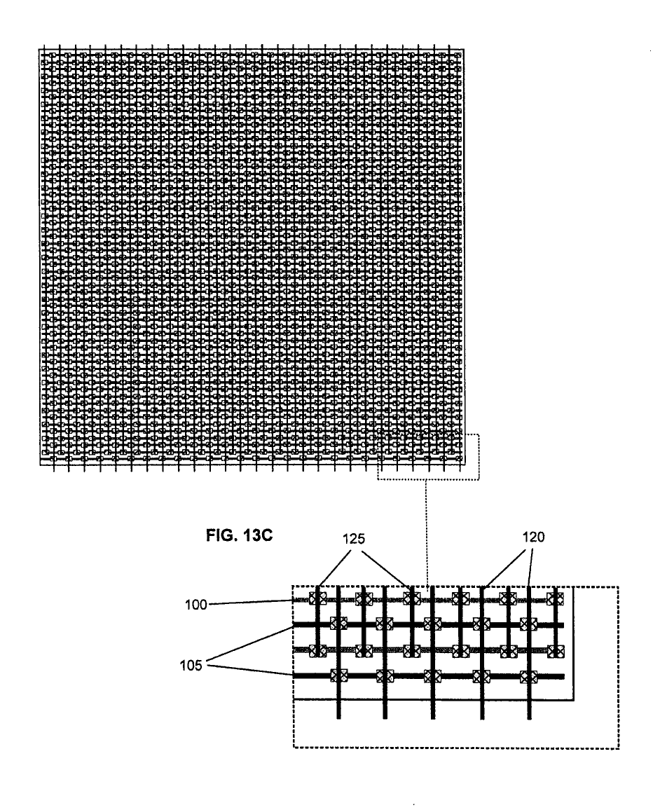

Standard silicon solar cells may be electrically interconnected by using wires coated with a low-temperature alloy that bond to the metallization on the solar cell during lamination. This technique can be applied to back-contact silicon solar cells as well. For example, a printed insulator can be applied over parallel grid lines 100, 105 as a plurality of pads 110 (FIGS. 13A and 13B). The electrical connection to the grid lines and the interconnect between solar cells is then preferably made during the lamination process using wires 120 coated with a low-temperature alloy (FIG. 13C). The wires will only connect to a single corresponding polarity, since the other polarity is coated with an insulating pad, preventing electrical connection. For example, wires 120 electrically connect to gridlines 100 but not to gridlines 105, which have the opposite polarity. Similarly, wires 125 electrically connect to gridlines 105 but not to gridlines 100. In this embodiment the wire interconnection process replaces the Cu ribbon or flex-circuit interconnect of the previous embodiment.

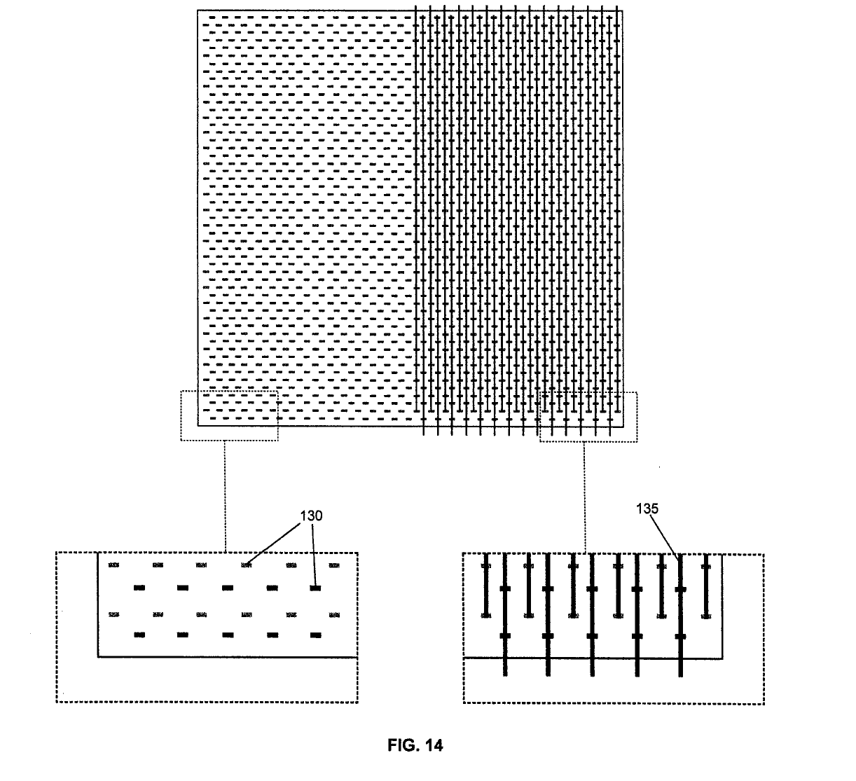

In another embodiment of the present invention, a wire laminated grid can entirely replace the grid lines on the solar cell. In this embodiment the metal on the solar cell preferably functions solely as Si-metal contacts and not as a conductive grid. The geometry of the contacts can therefore optionally be discontinuous, which allows new direct patterning techniques, including but not limited to shadow mask thin-film deposition or stencil printing, to be used. Thin-film metallizations typically have very low Si-metal contact resistances. The metal contacts 130 on the solar cell now only need to be large enough to accommodate tolerances in the wire lamination process. Unlike the previous embodiments, the discontinuous contacts permit the geometry to be adjusted so that a deposited insulator layer is not required, as shown in FIG. 14. That is, each wire 135 is in electrical contact with metal contacts 130 having the same polarity.

The busbarless EWT cell does not inherently have a metallization that is continuous across most of the solar cell surface. A continuous solar cell metallization pattern restricts the type of direct pattern deposition technologies that can be used. For example, stencil printing has superior printing characteristics compared to screen printing due to the absence of the screen's obstruction of the ink deposition. However, the stencil can not have a continuous pattern since it would otherwise not be physically stable. Similarly, thin-film metallization deposition can be directly patterned during deposition with a shadow mask—but the shadow mask cannot have a continuous pattern since the mask would otherwise not be physically stable. In general, these types of deposition techniques work better with discontinuous small features.

Thin-film metallizations generally have superior contact resistance properties. The metallization can also include several different metal layers in a stack for specific technical purposes. For example, the lowest layer in contact with the silicon may be selected for best contact resistance while overlying layers might be selected for adhesion, conductivity, electrical interconnection, and/or other properties.

### Monolithic Module Assembly

Monolithic module assembly refers to assembling the solar cell electrical circuit and encapsulating the photovoltaic modules all in a single step. The manufacturing cost is typically reduced compared to standard photovoltaic module assembly using conventional crystalline-silicon solar cells because the number of process steps is reduced. In any configuration, the backsheet of a photovoltaic module provides environmental protection. In monolithic module assembly, the module backsheet also comprises a patterned electrical circuit (“monolithic backsheet”). The patterned electrical circuit optionally includes a patterned insulator to help prevent unintended shunts. The encapsulant material may either be integrated with the monolithic backsheet or comprises a separate material added prior to the lamination step.

Busbarless EWT cells are well suited to monolithic module assembly. In the embodiments described above the interconnect is ordinarily deposited, adhered, or applied to the cell separately and prior to backsheet lamination, which allows for better optimization of materials and processes for each function, but requires more manufacturing steps. In monolithic module assembly the backsheet preferably comprises an electric circuit patterned to overlap the contacting regions on the solar cell. The electrical circuit may optionally include a patterned insulator so that it electrically contacts the cell only on the gridlines having the correct polarities. The electrical attachment may be achieved with conductive adhesives, solders, or other means. These materials preferably form the electrical interconnect during the typical lamination cycle. Alternatively, a localized heating source (e.g. a laser, inductive heater, focused lamp, etc.) can be used after the lamination step to form the electrical interconnect (e.g. via solder reflow, curing of conductive adhesive, etc.) for processes which require higher temperatures than the lamination temperature (e.g. high temperature solders). Laser soldering after lamination has been described for assembly of photovoltaic modules using conventional solar cells.

Photovoltaic modules typically use a thermoset material such as ethylene vinyl acetate (EVA) for the encapsulant. This material is typically laminated at peak temperatures around 150° C. For the present invention it may be advantageous to use an encapsulant material, such as a thermoplastic, having a higher lamination temperature to facilitate the formation of the electrical interconnect. Also, thermoplastic materials, such as a polyurethane, used for the encapsulant may be easier to integrate into a monolithic module assembly process than thermosetting materials, such as EVA, because they do not change phase.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all references, applications, patents, and publications cited above and/or in the attachments, and of the corresponding application(s), are hereby incorporated by reference.

1. A back contact solar cell module, comprising:
a plurality of back contact solar cells, each of the plurality of back contact solar cells having a first surface with gridlines disposed thereon;
insulating material disposed on the gridlines, the insulating material having holes therethrough; and
a plurality of conductive interconnects disposed on the insulating material, the plurality of conductive interconnects electrically coupled to the gridlines through the holes in the insulating material, wherein the plurality of conductive interconnects comprise an inset island freeform structure or an offset island freeform structure.

2. The back contact solar cell module of claim 1, wherein the plurality of conductive interconnects have an approximate shape selected from the group consisting of a rectangle, a triangle, and a diamond.

3. The back contact solar cell module of claim 2, wherein at least one of the plurality of conductive interconnects is positioned over an interior position of one of the back contact solar cells.

4. The back contact solar cell module of claim 2, wherein each of the plurality of back contact solar cells comprises a plurality of busbars, and at least one of the plurality of busbars is located at an interior position of each of the back contact solar cells.

5. The back contact solar cell module of claim 4, wherein the plurality of conductive interconnects are positioned above and parallel to the plurality of busbars.

6. The back contact solar cell module of claim 4, wherein each of the plurality of busbars includes a plurality of pads having a width greater than a width of each of the plurality of busbars.

7. The back contact solar cell module of claim 1, wherein the insulating material is a solder mask.

8. The back contact solar cell module of claim 1, wherein the plurality of conductive interconnects are formed from metallic foil or ribbon.

9. The back contact solar cell module of claim 8, wherein the metallic foil or ribbon comprises copper.

10. The back contact solar cell module of claim 1, wherein the plurality of back contact solar cells are busbarless.

11. A back contact solar cell module, comprising:
a plurality of back contact solar cells, each of the plurality of back contact solar cells having:
a first surface with gridlines disposed thereon; and
a plurality of busbars disposed on the first surface and electrically coupled to the gridlines;
insulating material disposed on the gridlines, the insulating material having holes therethrough exposing the gridlines; and
a plurality of conductive interconnects disposed on the insulating material, the plurality of conductive interconnects positioned over interior locations of the back contact solar cells and electrically coupled to the gridlines through the holes in the insulating material, wherein the plurality of conductive interconnects comprise an inset island freeform structure or an offset island freeform structure.

12. The back contact solar cell module of claim 11, wherein each of the plurality of busbars includes a plurality of pads having a width greater than a width of each of the plurality of busbars.

13. The back contact solar cell module of claim 12, wherein the plurality of conductive interconnects are electrically coupled to the gridlines using a conductive adhesive.

14. The back contact solar cell module of claim 13, wherein the insulating material is ethylene vinyl acetate.

15. The back contact solar cell module of claim 13, wherein a first set of the gridlines has a first polarity and a second set of the gridlines has a second polarity opposite the first polarity, and each of the plurality of conductive interconnects contacts only gridlines of the same polarity.

16. A back contact solar cell module, comprising:
a plurality of back contact solar cells, each of the plurality of back contact solar cells having:
a first surface with gridlines disposed thereon; and
a plurality of busbars having pads disposed on the first surface and electrically coupled to the gridlines;
insulating material disposed on the gridlines, the insulating material having holes therethrough exposing the gridlines; and
a plurality of copper interconnects disposed on the insulating material, the plurality of copper interconnects positioned over interior locations of the back contact solar cells and electrically coupled to the gridlines through the holes in the insulating material, wherein the plurality of copper interconnects comprise an inset island freeform structure or an offset island freeform structure.

17. The back contact solar cell module of claim 16, wherein a first set of the gridlines has a first polarity and a second set of the gridlines has a second polarity opposite the first polarity, and each of the plurality of conductive interconnects contacts only gridlines of the same polarity.

18. The back contact solar cell module of claim 16, wherein the insulating material is a solder mask.

19. The back contact solar cell module of claim 16, wherein the insulating material is ethylene vinyl acetate.
